(19) United States
(12) Patent Application Publication
(10) Pub. No.: US 2024/0136799 A1
(43) Pub. Date: Apr. 25, 2024

(54) Semiconductor optoelectronic device

(71) Applicant: 3SP Technologies, ÉVRY-COURCOURONNES CEDEX (FR)

(72) Inventor: Mauro BETTIATI, VILLEMOISSON SUR ORGE (FR)

(21) Appl. No.: 18/548,782

(22) PCT Filed: Mar. 4, 2022
(86) PCT No.: PCT/EP2022/055527

§ 371 Date: Aug. 31, 2023

(30) Foreign Application Priority Data
Mar. 5, 2021 (FR) 2102154

(51) Int. Cl. H01S 5/32

(52) U.S. Cl. CPC H01S 5/3216

(57) ABSTRACT

The present invention relates to a semiconductor optoelectronic device (10) comprising a junction (12) consisting a stack of layers defining an N-doped region, an intermediate region and a P-doped region, at least one layer, called a modulated layer, of the N-doped region and/or of the P-doped region and/or of the intermediate region, being formed of a plurality of stacks of sub-layers, each sub-layer differing from the other sub-layers of the same stack by a feature of the material of the sub-layer, called a distinctive feature, the thicknesses and distinctive features of the sub-layers being chosen so as to reduce the absorption of photons in the corresponding region compared with a semiconductor optoelectronic device, known as a reference device, the only difference being that each modulated layer is replaced by an unmodulated layer of the same thickness as the modulated layer and with identical features except for the distinctive feature.

The present invention relates to a semiconductor optoelectronic device, such as a semiconductor laser.

High power semiconductor lasers are used in many applications such as telecommunications.

The power of semiconductor lasers has been increasing steadily since the 1990's. In the present context, the term “power” means the reliable power of the laser, i.e. the power the laser can provide over the service life (usually 10-15 years) thereof. Such reliable power is thus generally different from the maximum power. Today, such lasers have in single-mode, a power exceeding one Watt, compared to 150 mW in the 1990's.

To meet the needs of different applications, it is of interest to develop even more powerful semiconductor lasers.

Increasing the power of such lasers involves reducing internal losses in the laser cavity. Indeed, the efficiency of the laser, defined as the power per unit of injected current, depends on two parameters, namely the injection of carriers into the active region, and the internal losses. Since the parameter relating to the carriers injected into the active region is already optimized, the increase in efficiency depends on the ability to reduce internal losses in the laser cavity.

The whole challenge is to reduce internal losses in order to maintain a high efficiency and thereby use a longer cavity for the laser. Indeed, when the cavity is longer, the laser operates at a lower current density since the injection is distributed throughout the length of the cavity. The temperature of the active region is also lower because a larger cavity leads to reducing the thermal resistance. Furthermore, the conversion efficiency of the laser, i.e. the ratio between the generated optical power and the injected electrical power, is also improved.

Thereby, the length of the laser cavities has continued to increase since the years 1990, going from 1.2 to 1.5 millimeters in the 1990's to currently reach 4 to 5 millimeters.

Since the internal losses are dependent on the level of doping of the semiconductor layers, a technique used for reducing the losses is to reduce the level of doping and to place the optical field as much as possible in the regions with the least absorption and thus the least losses. However, such a technique is limited because the level of doping of the materials cannot be reduced beyond the residual level of doping of the materials.

A goal of the invention is to propose an alternative for continuing to reduce internal losses in semiconductor optoelectronic devices, such as semiconductor lasers, in order to increase the efficiency and reliability of such devices.

To this end, the subject matter of the present description is a semiconductor optoelectronic device comprising a junction apt to emit or absorb light, the junction being formed of a stack of layers along a direction of stacking defining an N-doped region, an intermediate region and a P-doped region,

at least one so-called modulated layer of the N-doped region and/or the P-doped region and/or the intermediate region being formed of a plurality of stacks of sub-layers superimposed one on another along the direction of stacking,

each stack of sub-layers comprising at least two sub-layers, each sub-layer having a thickness along the direction of stacking and being made of at least one material, each sub-layer differing from the other sub-layers of the same stack by at least one feature of the at least one material of the sub-layer, called the distinctive feature,

each stack of a modulated layer being identical to the preceding superimposed stack or differing at most from the preceding superimposed stack by a bounded variation in the composition of at least one material of two corresponding sub-layers of the two stacks, the thicknesses and distinctive features of the sub-layers being chosen so as to reduce the absorption of photons by the free carriers (holes, electrons) in the corresponding region by modifying the electro-optical properties of the conduction band and/or the valence band, compared to a so-called reference semiconductor optoelectronic device, the only difference being that each modulated layer is replaced by an unmodulated layer, the unmodulated layer having the same thickness as the modulated layer and having identical features except for the at least one distinctive feature which is uniform or varies gradually over the thickness of the unmodulated layer.

According to particular embodiments, the device comprises one or more of the following features, taken individually or according to all technically possible combinations:
the modulated layer is a layer of the N-doped region or of the P-doped region, the junction being a PIN junction and the intermediate region being an intrinsic region;
the modulated layer is a layer of the N-doped region or the P-doped region, each of the N-doped region and the P-doped region comprising a core and a cladding, the optical index of the core being greater than the optical index of the cladding, the modulated layer being a layer of the core or of the cladding of the corresponding doped region, advantageously each of the core and of the cladding of the doped region considered comprising a modulated layer;
the at least one distinctive feature is the level of doping of the at least one material of the sub-layer;
the level of doping of each sub-layer differs from the level of doping of the other sub-layers of the same stack by at least one percent;
the average level of doping of the modulated layer is less than or equal to the level of doping of the corresponding unmodulated layer;
the level of doping of one of the sub-layers of each stack is the residual level of doping of at least one material the sub-layer is made of;
each sub-layer of a stack having a level of doping greater than the level of doping of another sub-layer of the stack having a thickness less than the thickness of said other sub-layer;
the at least one distinctive feature is the composition of the at least one material of the sub-layer;
at least one material of each sub-layer contains chemical elements belonging to columns III and V or II and VI or IV of the periodic table;
the thickness of each stack of sub-layers is comprised between 1 nanometer and 100 nanometers, preferentially greater than or equal to 5 nanometers, advantageously greater than or equal to 10 nanometers.
the thickness of each stack of sub-layers is chosen so as to reduce the absorption of photons by free carriers in the corresponding region, compared to the reference electronic device.
the modification of the electro-optical properties of the conduction band and/or the valence band is suitable for redistributing the oscillator strength of the spurious intra-band transition, at the origin of the absorption of photons by the free carriers, differently between the different polarizations of the photons circulating in the optoelectronic device, and in particular transferring most of the oscillator force of the intra-band transition to the polarization orthogonal to the polarization of the laser emission.
the modification of the electro-optical properties of the conduction band and of the valence band occurs through the production of a substantially two-dimensional modulated layer which generates discrete sub-bands in the conduction and valence bands.
each sub-layer of each stack contains no gallium nitride.

The present description also relates to a semiconductor optoelectronic device comprising a PIN junction apt to emit or absorb light, the PIN junction being formed of a stack of layers along a direction of stacking defining an N-doped region, an intrinsic region and a P-doped region,

at least one layer of one of the N-doped region and the P-doped region, known as the modulated layer, being formed of a plurality of stacks of sub-layers, superimposed on one another along the direction of stacking,

each stack of sub-layers comprising at least two sub-layers, each sub-layer having a thickness along the direction of stacking and being made of at least one material, each sub-layer differing from the other sub-layers of the same stack by at least one feature of the at least one material of the sub-layer, called the distinctive feature,

each stack of a modulated layer being identical to the preceding superimposed stack or differing at most from the preceding superimposed stack by a bounded variation in the composition of at least one material of two corresponding sub-layers of the two stacks, the thicknesses and distinctive features of the sub-layers being chosen so as to reduce the absorption of photons in the corresponding doped region, compared to a so-called reference semiconductor optoelectronic device, the only difference being that each modulated layer is replaced by an unmodulated layer, the unmodulated layer having the same thickness as the modulated layer and having identical features except for the at least one distinctive feature which is uniform or varies gradually over the thickness of the unmodulated layer.

Other features and advantages of the invention will appear upon reading hereinafter the description of the embodiments of the invention, given only as an example, and making reference to the following drawings:

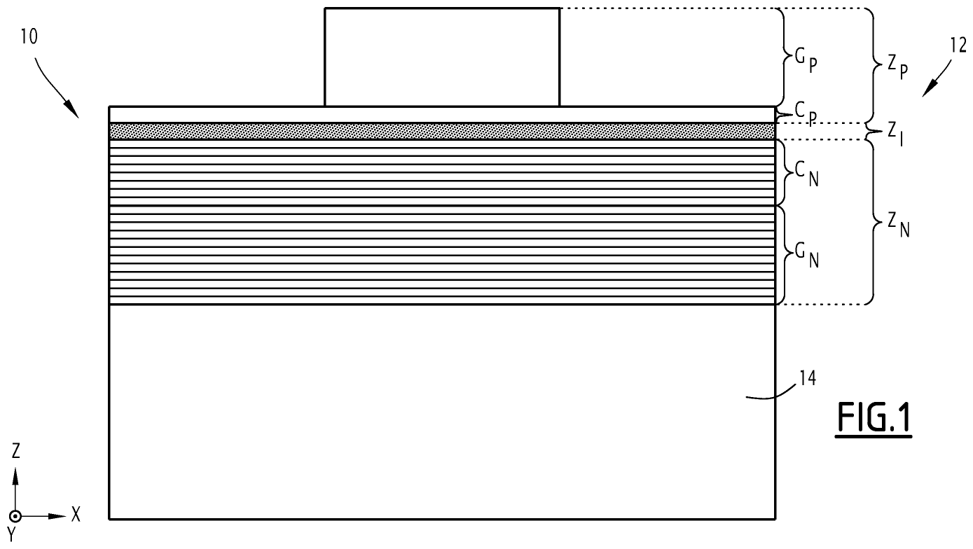

FIG. 1, a schematic sectional view of an example of a semiconductor laser according to a first example of embodiment,

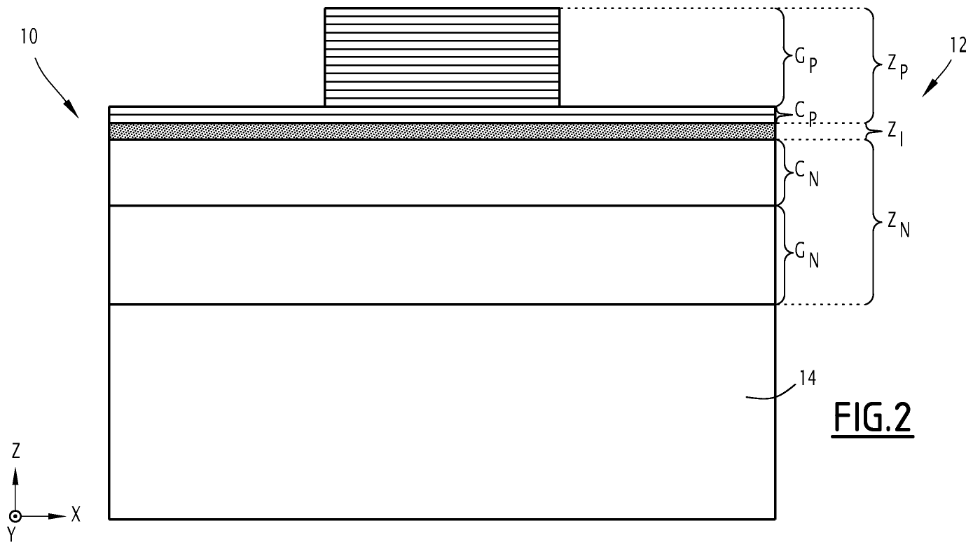

FIG. 2, a schematic sectional view of an example of a semiconductor laser according to a second example of embodiment, and

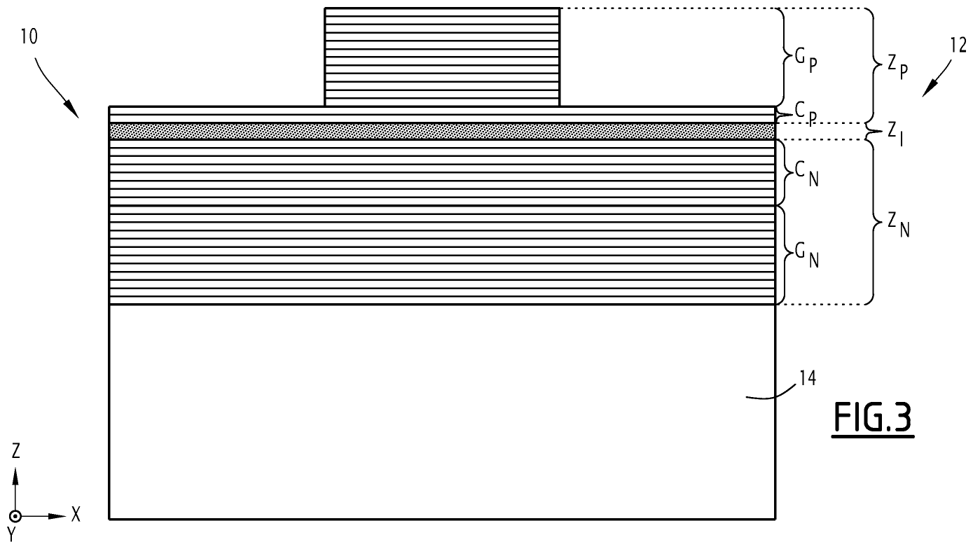

FIG. 3, a schematic sectional view of an example of a semiconductor laser according to a third example of embodiment.

A longitudinal direction is defined hereinafter in the description. A direction of stacking and a transverse direction are also defined. The direction of stacking is a direction perpendicular to the longitudinal direction and contained in a plane transverse to the longitudinal direction. The direction of stacking is perpendicular to the so-called longitudinal direction of propagation of light. The transverse direction is perpendicular to the longitudinal direction and to the direction of stacking. The longitudinal, stacking and transverse directions are symbolized by an axis Y, an axis Z and an axis X, respectively, in FIGS. 1 to 3.

Hereinafter, a semiconductor laser 10 comprising a PIN junction 12 apt to emit or absorb light, is considered. The laser is preferentially a high-power laser, i.e. apt to emit or absorb a laser beam having a power greater than 500 milliwatts (mW). Preferentially, the laser cavity has a length greater than 3 millimeters (mm) and less than 10 mm.

Such a laser is e.g. suitable for being used in the field of telecommunications, such as in an erbium-doped fiber amplifier. As an example, the laser is a GaAs (gallium arsenide) laser emitting at 980 nm.

The PIN junction 12 consists of a stack of layers along the direction of stacking Z.

Each layer of the stack is a planar layer, i.e. the layer extends between two planar and parallel faces.

Each layer also has a thickness along the direction of stacking Z. The thickness of a layer is defined as the distance between the two faces of the layer along the direction of stacking Z.

The layers of the stack define an N-doped region, an intrinsic region I and a P-doped region. The term “N-doped region” means a region into which impurities have been introduced so as to produce an excess of electrons. The term “intrinsic region” means a region into which no impurity has been intentionally added, the intrinsic region being the active region of the PIN junction 12. The intrinsic region I is a region wherein light is generated by recombination of electron-hole pairs. The term “P-doped region” means a region into which impurities have been added so as to produce an excess of holes.

Each of the N-doped region and the P-doped region comprises a core and a cladding, the optical index of the core being greater than the optical index of the cladding, leading to the formation of a waveguide. The core of each doped region and the cladding of each doped region correspond to one or a plurality of distinct layers of the stack.

FIGS. 1 to 3 are examples illustrating the stack of layers forming the PIN junction 12. In said examples, the layers forming the stack are superimposed along the direction of stacking Z on a substrate 14. In said figures, the N-doped region is denoted by Z_{N}, the intrinsic region by Z_{I} and the P-doped region, by Z_{P}. The core of the N-doped region is denoted by C_{N}, the core of the P-doped region by C_{P}, the cladding of the N-doped region is denoted by G_{N} and the cladding of the P-doped region by G_{P}.

For example, when the laser 10 is a GaAs laser, the substrate 14 is made of GaAs.

At least one layer of one of the N-doped region and of the P-doped region, called the modulated layer, consists of a plurality of stacks of sub-layers along the direction of stacking Z. In other words, at least one modulated layer is one amongst the layers of the N-doped region and of the P-doped region

Each sub-layer stack comprises at least two sub-layers superimposed along the direction of stacking Z. Each stack of sub-layers can be considered as a pattern repeated as many times as the number of stacks of sub-layers.

The modulated layer is a layer of the core or of the cladding of the doped region in question. Advantageously, the doped region in question comprises at least one modulated layer belonging to the core and one modulated layer belonging to the cladding.

FIG. 1 illustrates an example wherein only the N-doped region comprises modulated layers, namely a modulated layer forming the core and a modulated layer forming the cladding of the N-doped region. FIG. 2 illustrates an example wherein only the P-doped region comprises a modulated layer, namely a modulated layer forming the core and a modulated layer forming the cladding of the P-doped region. FIG. 3 illustrates an example wherein each of the N-doped region and of the P-doped region comprises modulated layers (a modulated layer for each amongst the core and the cladding of the P- and N-doped regions).

The sub-layer stacks are superimposed on each other along the direction of stacking Z so that the thickness of all the sub-layer stacks (sum of the thicknesses of the sub-layers forming the stack) is equal to the thickness of the modulated layer.

Preferentially, the number of stacks of sub-layers forming a modulated layer is greater than or equal to 10. Thereby, the total thickness of the modulated layer is typically comprised between 10 nm and 10 μm, when the thickness of each stack of sub-layers is comprised between 1 nanometers and 100 nanometers.

Each sub-layer is a planar sub-layer, i.e. that the sub-layer extends between two plane and parallel faces.

Each sub-layer has a thickness along the direction of stacking Z. The thickness of an underlay is defined as the distance between the two faces of the underlay along the direction of stacking Z. The thickness of each sub-layer is strictly less than the thickness of the corresponding modulated layer. Preferentially, the thickness of each sub-layer is greater than or equal to 1 nanometer (nm) and less than or equal to 100 nm.

Preferentially, the thickness of each stack of sub-layers is comprised between 1 nanometer and 100 nanometers.

Each sub-layer is made of at least one material.

Advantageously, the at least one material of each sub-layer consists of a plurality of chemical elements. A chemical element is an element of Mendeleev's table. Preferentially, the elements belong to columns III and V or II and VI or IV of the periodic table. For example, the material is aluminum gallium arsenide (AlGaAs) or indium phosphide (InP) or the alloys InGaAsP or InGaAlAs thereof.

In one embodiment, each sub-layer is made of one material. In a variant, at least one sub-layer is made of a plurality of materials, the materials being formed of the same chemical elements but differing in the composition (proportion) of chemical elements.

Each sub-layer differs from the other sub-layers of the same stack by at least one feature of the at least one material of the sub-layer, referred to as the distinctive feature.

Preferentially, the distinctive features are at least one amongst the level of doping of the material of each sub-layer and the composition of the material of the sub-layer. The level of doping is defined as the number of doping impurities (electron donors or electron acceptors) in a cubic centimeter of the crystal lattice. The level of doping is by volume. Composition is defined as the proportion of the chemical elements forming the material.

Otherwise formulated, in such embodiment, for two materials of two distinct sub-layers of the same stack, three cases are possible:
the two materials have the same composition but a different level of doping,
the two materials have the same level of doping but a different composition, and
the two materials have a different level of doping and a different composition.

In one embodiment, the stacks forming a modulated layer are identical. Thereby, each stack of a modulated layer is identical to the previous superimposed stack. The previous stack is the stack on which the stack in question is superimposed.

In a variant of embodiment, at least one stack differs from the other stacks.

In said variant, each stack preferentially differs from the preceding superimposed stack at most by a bounded variation in the composition of the at least one material of each sub-layer of the stack compared to the composition of the at least one material of the corresponding sub-layers of the preceding superimposed stack (the or at least one material of two corresponding sub-layers of two stacks have different compositions). In other words, from one stack to another, the number of sub-layers, the thickness of the sub-layers, the chemical elements of the sub-layer materials and the levels of doping are identical. However, the composition of a material of a sub-layer of a stack is either increased or decreased (by a given value within the bounded variation) compared to the composition of the corresponding sub-layer of the previous stack.

The term “at most” means that the variation in composition is the only difference, and that same could be zero, in which case the stacks considered are identical.

The term “corresponding sub-layer” refers to the sub-layer of the other stack having the same position in the other stack as the sub-layer of the stack considered. Thereby, for example, the sub-layer of the first stack closest to the base of the first stack is compared with the sub-layer of the second stack closest to the base of the second stack, and so on for the other sub-layers.

The term “bounded variation” means that the compositions of the materials of the two sub-layers of the two stacks considered differ from each other by a percentage within a predetermined range of values. For example, the variation in composition is comprised between 0 and 2 percent.

In such variant, the variation is preferentially gradual over the thickness of the modulated layer, i.e. leads to an increase or to a decrease in the overall composition over the thickness of the modulated layer.

For example, as illustration of such variant, the modulated layer comprises three superimposed stacks, each being formed of two sub-layers. The distinctive feature is the composition of the materials of the sub-layers. The first stack and the second stack are identical and comprise:
a first, 10 nm thick, sub-layer of Al_{0.28}Ga_{0.72}As with a level of doping (Si atoms) of 5×10¹⁶ cm⁻³, and
a second, 20 nm thick, sub-layer of Al_{0.32}GA_{0.68}As with a level of doping (Si atoms) of 5×10¹⁶ cm⁻³.

The third stack comprises:
a first, 10 nm thick, sub-layer of Al_{0.29}Ga_{0.71}As with a level of doping (Si atoms) of 5×10¹⁶ cm⁻³, and
a second, 20 nm thick, sub-layer of Al_{0.33}GA_{0.67}As with a level of doping (Si atoms) of 5×10¹⁶ cm⁻³.
The third stack of the present example thus has a variation (of 0.01) in the composition of the material of the sub-layers compared to the corresponding sub-layers of the first and second stacks.

The thicknesses and distinctive features of the sub-layers are chosen so as to reduce the absorption of photons in the corresponding doped region compared with a so-called reference semiconductor laser. Such absorption of photons is a spurious phenomenon due to the absorption of photons from the active region by the free carriers (holes or electrons) of a doped region. Such phenomenon is also called “free-carrier absorption”.

The reference laser differs from the laser considered only in that each modulated layer is replaced by an unmodulated layer. The unmodulated layer has the same thickness as the corresponding modulated layer and has identical features except for the distinctive feature which is uniform (within the limits of the technologies used) or varies gradually over the thickness of the unmodulated layer.

The term “uniform” means that the value of the distinctive feature is the same over the thickness of the unmodulated layer. Thereby, when a distinctive feature is the level of doping of the materials of the sub-layers, the level of doping of the material of the unmodulated layer has the same value over the thickness of the unmodulated layer. When a distinctive feature is the composition of the sub-layer materials, the composition of the material of the unmodulated layer is the same over the thickness of the unmodulated layer.

The term “gradual variation” means that the value of the distinctive feature is either progressively increased or decreased over the thickness of the unmodulated layer.

In one example, the absorption of photons in the doped region considered is quantified by performing a regression of the external efficiencies of lasers of different lengths, as a function of the cavity length as such. Such a regression is described e.g. in the book entitled “Diode Lasers and Photonic Integrated Circuits.” Chap. 2 (1995) from Coldren, L. et al.

Preferentially, the photon absorption in the region under consideration is reduced by at least 0.1 cm⁻¹ compared to the reference laser.

Preferentially, the PIN junction 12 has been obtained exclusively by epitaxy from the substrate 14. Epitaxy is understood as a technique for growing a crystal on another crystal, each crystal comprising a crystal lattice having a number of symmetry elements in common with the other crystal. The epitaxy technique used is e.g. chosen from: molecular beam epitaxy, liquid phase epitaxy and organometallic vapor phase epitaxy.

Thereby, the production of a modulated layer consisting in an alternation of repeating specific sub-layers, instead of a uniform layer or a gradual variation layer, makes it possible to modify the absorption of photons by the free carriers of the doped regions considered, and thereby to reduce internal losses. In other words, the structure of the modulated layer makes it possible to modify the electro-optical properties of the conduction band when the modulated layer belongs to the N-doped region and in the valence band when the modulated layer belongs to the P-doped region. Such modification is one of the factors which contribute to inhibiting the absorption of photons by the free carriers of the doped regions considered.

Hereinafter, advantageous features of the structure of the modulated layer are given in the case where a distinctive feature is the level of doping of the materials of the sub-layers. In such case, a structure of doping superlattices is created. The superlattices (SR) are typically of the n-i-n-i type for the N layers or of the p-i-p-i type for the P layers.

Preferentially, the level of doping of each sub-layer differs from the level of doping of the other sub-layers of the same stack by at least one percent.

Preferentially, the average of the level of doping of the modulated layer (obtained from the level of doping of the sub-layers taking into account the thicknesses thereof) is less than or equal to the level of doping of the corresponding unmodulated layer (of the reference laser). Thereby, the structure with repeated stacks of sub-layers makes it possible to reduce the average level of doping with respect to a layer having the same level of doping over the thickness thereof.

Preferentially, the level of doping of one of the sub-layers of each stack is the residual level of doping of the material the sub-layer is made of. The residual level of doping is the level of doping obtained even though no impurity has been intentionally added into the material. Thereby, in the case where each stack comprises only two sub-layers, the modulated layer consists of a repeated alternation over the thickness of the modulated layer, of a doped sub-layer and of an intrinsic doping sub-layer.

Preferentially, each sub-layer of a stack having a level of doping greater than the level of doping of another sub-layer of the same stack has a thickness less than the thickness of said other sub-layer.

A particular example resulting from an experimental embodiment is described hereinafter.

In such example, a 980 nm GaAs laser structure has been produced according to two variants, namely:
a standard laser structure forming the reference laser. Said structure was produced on the principle of the structure described in the article entitled “Reaching 1 watt reliable output power on single-mode 980 nm pump lasers” by M. Bettiati et al., Proc. SPIE 7198, High-Power Diode Laser Technology and Applications VII, 71981D (23 Feb. 2009). In said structure, the N-doped region comprises:
   a first non-modulated layer forming the 3 μm thick cladding with a level of doping (Si atoms) constant at 5×10¹⁶ cm⁻³ and a matrix of AlGaAs material, and
   a second unmodulated layer forming the core with a thickness of 900 nm with a level of doping (Si atoms) constant at 5×10¹⁶ cm⁻³ and a matrix of AlGaAs material.
an equivalent laser structure with the difference that the first, respectively the second, non-modulated layer is replaced by a first, respectively a second, modulated layer of the same thickness and being formed of a plurality of identical and superimposed stacks of sub-layers. Each stack of sub-layers comprises two sub-layers. The first sub-layer of each stack has a thickness of 10 nm and a level of doping (Si atoms) constant at 6×10¹⁶ cm⁻³ and the second sub-layer of each stack has a thickness of 20 nm and a level of doping (Si atoms) constant at 2.5×10¹⁶ cm⁻³ (residual doping level in the material). Thereby, the first modulated layer (cladding) consists of 100 stacks (3 μm thick and 30 nm thick per stack) and the second modulated layer (core) consists of 30 stacks.

Such approach therefore makes it possible to compare a structure integrating the principle of alternating sub-layers with a periodicity in level of doping (also called digital doping) in the N-doped region, compared to a standard structure the performance of which is known. In said approach, the comparison was made on a key parameter of power lasers, called efficiency and which quantifies the laser emission efficiency of the component. It is often referred to as SE (Slope Efficiency) and is measured in Watts per Ampere (W/A). The technical expression of this parameter is defined e.g. in the book entitled “Diode Lasers and Photonic Integrated circuits.” Chap. (2 (1995) of Coldren, L. et al, namely:

$$S E = {η}_{i} \cdot \frac{( \frac{hv}{e} {α}_{m} )}{{α}_{i} + {α}_{m}}$$

### Where:

ηᵢ is the internal quantum efficiency, defined as the fraction of carriers injected into the active region,
h is Planck's constant,
v is the frequency of the laser emission,
e is the charge of the electron,
αᵢ are the internal losses, and
αₘ are the mirror losses (αₘ=(1/L)ln(1/R) for a multi-faceted laser having the same reflectivity R; L being the length of the laser).

The expression SE clearly shows the internal losses αᵢ. Thereby, it is clear that the reduction in internal losses αᵢ leads to an increase in the efficiency SE.

For a laser with a cavity length of 3.9 mm, the efficiency obtained, measured under short pulse injection conditions (<1 μs), is 0.460 W/A with a standard structure, and of 0.494 W/A with a modified structure (sub-layers). Since 0.494/0.460=1.074, the increase in laser efficiency is about 7%. Thereby, the increase in the efficiency SE shows that the sub-layer structure leads to reducing internal losses. However, it should be noted that such first achievement was made with lasers with a cavity length of 3.9 mm. The increase in efficiency is expected at higher values for lasers with a longer cavity, reasonably up to maximum lengths of 8 to 10 mm. For such cavities, it is estimated that the efficiency increase could be as high as 10 to 11%. For lasers with a large surface area (active region width of 100 μm), with a cavity length of 10.2 mm, as an example, a gain of 10 to 11% was found, since the SE has gone from 0.36 to 0.40 W/A.

It should be noted that by also modifying the layers of the P-doped region, it is possible to reduce the internal losses even further and thus increase the efficiency of the laser even further.

In another example, the modulated layer comprises identical stacks of the following sub-layers each comprising:
a first 10 nm thick AlGaAs sub-layer with a level of doping (Si atoms) of 6×10¹⁶ cm⁻³, and
a second 25 nm thick AlGaAs sub-layer with a level of doping (Si atoms) of 5×10¹⁶ cm⁻³.

In yet another example, the modulated layer comprises identical stacks of the following sub-layers each comprising:
a first, 15 nm thick, InP sub-layer with a level of doping (Si atoms) of 6×10¹⁶ cm⁻³, and
a second, 30 nm thick, InP sub-layer with a level of doping (Si atoms) of 3×10¹⁶ cm⁻³.

In yet another example, the modulated layer comprises identical stacks of the following sub-layers each comprising:
a first, 10 nm thick, sub-layer of Al_{0.28}Ga_{0.72}As with a level of doping (Si atoms) of 5×10¹⁶ cm⁻³, and
a second, 20 nm thick, sub-layer of Al_{0.32}GA_{0.68}As with a level of doping (Si atoms) of 5×10¹⁶ cm⁻³.

In yet another example, the modulated layer comprises identical stacks of the following sub-layers each comprising:
a first, 10 nm thick, sub-layer of Al_{0.28}Ga_{0.72}As with a level of doping (Si atoms) of 6×10¹⁶ cm⁻³, and
a second, 20 nm thick, sub-layer of Al_{0.32}GA_{0.68}As with a level of doping (Si atoms) of 2.5×10¹⁶ cm⁻³.

In yet another example, the modulated layer comprises identical stacks of the following sub-layers each comprising:
a first, 10 nm thick, sub-layer of Al_{0.28}Ga_{0.72}As with a level of doping (Si atoms) of 6×10¹⁶ cm⁻³, and
a second, 20 nm thick, sub-layer of Al_{0.32}GA_{0.68}As with a level of doping (Si atoms) of 2.5×10¹⁶ cm⁻³, and
a third, 10 nm thick, sub-layer of Al_{0.3}GA_{0.7}As with a level of doping (Si atoms) of 4×10¹⁶ cm⁻³

Thereby, the laser structure described makes it possible, by means of a periodically repeated alternation of sub-layers having different features (level of doping and/or composition), to reduce internal losses due to the absorption of photons by the free carriers of the doped regions of the PIN junction. The efficiency and reliability of the laser is thereby increased. Furthermore, a significant reduction in internal losses can increase, in addition to the purely optical efficiency of the laser, the total conversion efficiency of the component, expressed as the ratio of the total optical power emitted by the normalized Pₒₚₜ laser with respect to the total electrical power injected into the laser and which is equal to the product I×V (product of the current injected into the laser and the voltage needed to inject same).

A person skilled in the art would understand that the embodiments described hereinabove can be combined to form new embodiments provided that the embodiments are technically compatible and that the invention described herein is not limited to the embodiments specifically described and that any other equivalent embodiment should be assimilated to the present invention. More particularly, although the invention has been described in the case of a semiconductor laser, the invention applies to all semiconductor optoelectronic devices, in particular to photodetectors or to photovoltaic cells. In such case, the term laser should be replaced in the description by the term semiconductor optoelectronic device.

Furthermore, it should be noted that the modification of the electro-optical properties of the conduction band and/or the valence band makes it possible to redistribute the oscillator strength of the spurious intra-band transition (at the origin of photon absorption by free carriers) differently between the different polarizations of the photons (circulating in the laser cavity of the optoelectronic device), and particularly to transfer most (or even all) of the oscillator strength of the intra-band transition to the polarization orthogonal to the polarization of the laser emission. In this way it is possible to decouple the laser emission almost completely from the transition responsible for absorption by free carriers.

More particularly, it should be noted that when the modulated layer is either in the N-doped region or in the P-doped region, but not both at the same time, the modulated layer does not impart a beneficial effect on the reduction of photon absorption by free carriers, in the conduction band for a modulated layer in the N-doped region or in the valence band for a modulated layer in the P-doped region. On the other hand, the electro-optical properties of the conduction band and of the valence band are generally modified by the modulated layer in both cases, in particular because the material has a quasi-two-dimensional character.

In addition, the modification of the electro-optical properties of the conduction band and the valence band occurs by the production of a quasi-2D modulated layer (the doping superlattice and/or composition superlattice), which is essentially two-dimensional, which generates discrete sub-bands in the conduction and the valence bands. Furthermore, in the modulated layer, the selection rules and the distribution of the oscillator strengths of the intra-band transitions for the different polarizations are advantageously different with respect to an isotropic three-dimensional material not having such specific structure (the fact that the material is isotropic means that the oscillator strengths are the same along all three directions.)

It should also be noted that, in addition to the thicknesses and the distinctive features of the sub-layers, the thickness of each stack of sub-layers is preferentially also chosen so as to reduce the absorption of photons by free carriers in the corresponding doped region with respect to the reference electronic device.

Preferentially, the thickness of each stack of sub-layers is greater than or equal to 5 nm, preferentially greater than or equal to 10 nm.

It should also be noted that each modulated layer is different from a Short Period Superlattice (SPSL).

In a particular embodiment (supplement or variant), it should be noted that each sub-layer of each stack does not contain any gallium nitride (GaN).

In a particular embodiment (supplement or variant), it should be noted that the modulated layer is at least one layer of the core of the corresponding doped region.

A person skilled in the art would understand that the optoelectronic device described is more particularly suitable for III-V semiconductors with a so-called ‘diamond’ crystal structure or with a zinc-blende structure.

Moreover, in an alternative embodiment, the modulated layer described hereinabove is also applicable to a semiconductor optoelectronic device comprising a junction formed by a stack of layers along a direction of stacking defining an N-doped region, an intermediate region (between the N-doped region and the P-doped region) and a P-doped region. In such case, the modulated layer is a layer belonging to the intermediate region, and e.g. more precisely to the active region (region where the recombination of the charge carriers takes place). More particularly, the modulated layer is e.g. a layer of the active (isotropic) region of a Double Heterostructure (DH) laser with sufficient thickness for integrating a plurality of periods of modulation of the distinctive feature. The thickness considered is e.g. greater than or equal to 100 nm.

Thereby, in such alternative embodiment, all the features of the embodiments described hereinabove in the description are applicable, the only differences being the junction which is not necessarily a PIN junction and the intermediate region which is not necessarily intrinsic, as well as the integration of the modulated layer into the intermediate region. It should be noted that in the preceding embodiments, the intrinsic region corresponds to the intermediate region.

More particularly, in such alternative embodiment, in the case where the distinctive feature is a composition of a material, the intermediate region could be an intrinsic region. On the other hand, when the distinctive feature is a level of doping, the intermediate region is different from an intrinsic region (since same is doped via the modulated layer). When the intermediate region is doped, the doping is an N doping and/or an P doping.

Such an alternative embodiment is also compatible with the integration of other modulated layers into the N-doped region and/or the P-doped region.

1. A semiconductor optoelectronic device comprising a junction apt to emit or absorb light, the junction being formed of a stack of layers along a direction of stacking defining an N-doped region, an intermediate region and a P-doped region,
at least one so-called modulated layer of the N-doped region and/or the P-doped region and/or the intermediate region being formed of a plurality of stacks of sub-layers superimposed one on top of the other along the direction of stacking,
each stack of sub-layers comprising at least two sub-layers, each sub-layer having a thickness along the direction of stacking and being made of at least one material, each sub-layer differing from the other sub-layers of the same stack by at least one feature of the at least one material of the sub-layer, called the distinctive feature,
each stack of a modulated layer being identical to the preceding superimposed stack or differing at most from the preceding superimposed stack by a bounded variation in the composition of at least one material of two corresponding sub-layers of the two stacks, the thicknesses and distinctive features of the sub-layers being chosen so as to reduce the absorption of photons by free carriers in the corresponding region by modifying the electro-optical properties of the conduction band and/or the valence band, compared to a so-called reference semiconductor optoelectronic device, the only difference being that each modulated layer is replaced by an unmodulated layer, the unmodulated layer having the same thickness as the modulated layer and having identical features except for the at least one distinctive feature which is uniform or varies gradually over the thickness of the unmodulated layer.

2. The device according to claim 1, wherein the modulated layer is a layer of the N-doped region or of the P-doped region, the junction being a PIN junction and the intermediate region being an intrinsic region.

3. The device according to claim 1, wherein the modulated layer is a layer of the N-doped region or the P-doped region, each of the N-doped region and the P-doped region comprising a core and a cladding, the optical index of the core being greater than the optical index of the cladding, the modulated layer being a layer of the core or of the cladding of the corresponding doped region.

4. The device according to claim 1, wherein the at least one distinctive feature is the level of doping of the at least one material of the sub-layer.

5. The device according to claim 4, wherein the level of doping of each sub-layer differs from the level of doping of the other sub-layers of the same stack by at least one percent.

6. The device according to claim 4, wherein the average level of doping of the modulated layer is less than or equal to the level of doping of the corresponding unmodulated layer.

7. The device according to claim 4, wherein the level of doping of one of the sub-layers of each stack is the residual level of doping of the at least one material the sub-layer is made of.

8. The device according to claim 4, wherein each sub-layer of a stack having a level of doping greater than the level of doping of another sub-layer of the stack has a thickness less than the thickness of said other sub-layer.

9. The device according to claim 1, wherein the at least one distinctive feature is the composition of the at least one material of the sub-layer.

10. The device according to claim 1, wherein the at least one material of each sub-layer comprises chemical elements belonging to columns III and V or II and VI or IV of the periodic table.

11. The device according to claim 1, wherein the thickness of each stack of sub-layers is between 1 nanometer and 100 nanometers.

12. The device according to claim 1, wherein the thickness of each stack of sub-layers is selected so as to decrease the absorption of photons by free carriers in the corresponding region, compared to the reference electronic device.

13. The device according to claim 1, wherein the modification of the electro-optical properties of the conduction band and/or the valence band is suitable for redistributing the oscillator strength of the spurious intra-band transition, at the origin of the absorption of photons by the free carriers, differently between the different polarizations of the photons circulating in the optoelectronic device.

14. The device according to claim 1, wherein the modification of the electro-optical properties of the conduction band and the valence band occurs through the formation of a substantially two-dimensional modulated layer which generates discrete sub-bands in the conduction band and the valence band.

15. The device according to claim 1, wherein each sub-layer of each stack does not contain any gallium nitride.

16. The device according to claim 3, wherein each of the core and of the cladding of the considered doped region comprises a modulated layer.

17. The device according to claim 1, wherein the thickness of each stack of sub-layers is greater than or equal to 5 nanometers.

18. The device according to claim 1, wherein the thickness of each stack of sub-layers is greater than or equal to 10 nanometers.

19. The device according to claim 13, wherein the modification of the electro-optical properties of the conduction band and/or the valence band is suitable for redistributing the oscillator strength of the spurious intra-band transition, to transfer most of the oscillator strength of the intra-band transition to the polarization orthogonal to the polarization of the laser emission.
